(19) United States
(12) Patent Application Publication
(10) Pub. No.: US 2024/0224731 A1
(43) Pub. Date: Jul. 4, 2024

(54) DISPLAY DEVICE

(71) Applicant: Samsung Display Co., LTD., Yongin-si (KR)

(72) Inventor: Jong Soo LEE, Yongin-si (KR)

(73) Assignee: Samsung Display Co., LTD., Yongin-si (KR)

(21) Appl. No.: 18/529,575

(22) Filed: Dec. 5, 2023

(30) Foreign Application Priority Data
Dec. 29, 2022 (KR) 10-2022-0189356

(51) Int. Cl. H10K 59/80; H10K 77/10

(52) U.S. Cl. CPC H10K 59/873; H10K 59/8722; H10K 59/8791; H10K 77/111; H10K 2102/311

(57) ABSTRACT

A display device according to an embodiment includes a display panel including a main display area that displays images and an edge region disposed adjacent to the main display area; a protection film disposed below the display panel; and at least one additional layer disposed below the protection film, wherein the edge region includes a corner portion disposed on a corner, and the at least one additional layer overlap the corner portion and are spaced from each other.

### CROSS-REFERENCE TO RELATED APPLICATION

This application claims priority to and the benefit of Korean Patent Application No. 10-2022-0189356 under 35 U.S.C. § 119 filed in the Korean Intellectual Property Office on Dec. 29, 2022, the entire contents of which are incorporated herein by reference.

### BACKGROUND

### 1. Technical Field

The disclosure relates to a display device, and specifically relates to a display device including a bent edge region.

### 2. Description of the Related Art

A display device includes a substrate and transistors and light-emitting devices formed on the substrate. Recently, to accept various design demands, the display device may include a flexible display panel including a flexible substrate. The display device may further include various layers, such as a polarizer, a cover window, or a protection film, overlapping the display panel.

The display device includes a display area for displaying images, and an edge region is disposed around the display area. The edge region may include a non-display area for displaying no images, or may include the display area. The non-display area included by the edge region is a bezel region, and the display device with the minimized bezel region is required.

To satisfy the design requirements or minimize the bezel region, the display device with the bent edge region is currently being developed.

The display device with at least two bent sides neighboring each other from among the display device with the bent edge region includes a corner portion on which two edge regions extending in different directions meet each other and are bent. The display device with the bent edge regions on four sides may include two bent corner portions.

The above information disclosed in this Background section is only for enhancement of understanding of the background of the disclosure, and therefore it may contain information that does not form the prior art that is already known in this country to a person of ordinary skill in the art.

### SUMMARY

The disclosure has been made in an effort to prevent defects of a display device generated by compressing stresses at a corner portion of a display device.

The technical objectives to be achieved by the disclosure are not limited to those described herein, and other technical objectives that are not mentioned herein would be clearly understood by a person skilled in the art from the description of the disclosure.

An embodiment of the disclosure provides a display device including a display panel including a main display area that displays images and an edge region disposed adjacent to the main display area; a protection film disposed below the display panel; and at least one additional layer disposed below the protection film, wherein the edge region includes a corner portion disposed on a corner, and the at least one additional layer overlap the corner portion and are spaced from each other.

The at least one additional layer may include a resin.

The at least one additional layer may contact a rear side of the protection film.

The display device may further include a first adhesive layer disposed between the at least one additional layer and the protection film.

The at least one additional layer may include a metal.

The display device may further include a first adhesive layer disposed between the at least one additional layer and the protection film.

The at least one additional layer may include a first additional layer and a second additional layer spaced from each other with a corner portion center line passing through a center of an edge of the corner portion.

The at least one additional layer may further include a third additional layer spaced from the first additional layer and a fourth additional layer spaced from the second additional layer, and the third additional layer and the fourth additional layer may be spaced from each other with the corner portion center line between the third additional layer and the fourth additional layer.

The at least one additional layer may include a first side corresponding to a first edge of the protection film; a second side connected to a first end of the first side, and a third side connected to a second end of the first side and facing the second side.

The at least one additional layer may further include a fourth side connected to the second side and the third side, and the fourth side may face the first side.

The corner portion may be bent with a curvature radius.

The edge region may further include a first lateral edge region and a second lateral edge region connected to the corner portion, the first lateral edge may be bent with a first curvature radius, and the second lateral edge may be bent with a second curvature radius.

A curvature radius of the corner portion may be changed according to positions.

The display device may further include a polarization layer disposed on the display panel; and a cover window disposed on the polarization layer, wherein the cover window that corresponds to the edge region may be bent.

In case that a distance in a front direction between a point on which a virtual straight line extending in the front direction from an edge of the polarization layer that corresponds to the corner portion contacts a rear side of the cover window and a point on which the cover window starts being bent is set to be a Z-overlap, the Z-overlap may be substantially equal to or greater than about 400 micrometers.

Another embodiment of the disclosure provides a display device including a display panel including a main display area that displays images and an edge region disposed adjacent to the main display area; a protection film disposed below the display panel in a rear direction; a support member that is rigid and disposed below the protection film; and at least one additional layer disposed between a rear side of the protection film and the support member, wherein the edge region includes a corner portion disposed on a corner, and the at least one additional layer contacts the corner portion.

The at least one additional layer may be spaced from each other, and the at least one additional layer may each have an island shape.

The at least one additional layer may include a resin or a metal.

The corner portion and the protection film overlapping the corner portion may be bent.

Another embodiment of the disclosure provides a display device including a display panel including a main display area that displays images and an edge region disposed adjacent to the main display area; a protection film disposed below the display panel; and a support member that is rigid and is disposed below the protection film, wherein the edge region includes a corner portion disposed on a corner, and thickness of the protection film overlapping the corner portion follows positions.

According to the embodiments, the defects in the display device caused by the compressing stress at the corner portion of the display device with the bent edge region may be prevented.

### BRIEF DESCRIPTION OF THE DRAWINGS

FIG. 1 shows a schematic front top plan view of a display device according to an embodiment.

FIG. 2 shows a schematic rear top plan view of a display device according to an embodiment.

FIG. 3 shows a schematic cross-sectional view of a display device with respect to a line A1-A2 of FIG. 1.

FIG. 4 shows another schematic cross-sectional view of a display device with respect to a line A1-A2 of FIG. 1.

FIG. 5 shows a rear side view of a corner portion of a display device according to an embodiment.

FIG. 6 shows a schematic cross-sectional view of a corner portion of a display device according to an embodiment.

FIG. 7 shows a perspective view of a corner portion of a display panel included by a display device and compressing stress applied to a corner portion according to a comparative example.

FIG. 8 shows a schematic cross-sectional view of a corner portion of a display device according to a comparative example.

FIG. 9 shows compressing stresses applied to a corner portion of a display panel included by a display device according to a comparative example and compressing stresses applied to a corner portion of a display panel included by a display device according to an embodiment.

FIG. 10, FIG. 11, and FIG. 12 each show a rear side view of a corner portion of a display device according to an embodiment.

### DETAILED DESCRIPTION OF THE EMBODIMENTS

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

The drawings and description are to be regarded as illustrative in nature and not restrictive, and like reference numerals and/or reference characters designate like elements throughout the specification.

The size and thickness of each configuration shown in the drawings are arbitrarily shown for better understanding and ease of description, but the disclosure is not limited thereto. The thickness of layers, films, panels, regions, etc., may be enlarged for clarity. The thicknesses of some layers and areas may be exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned “on” or “above” the upper side of the object portion based on a gravitational direction.

Unless explicitly described to the contrary, the word “comprise,” “include,” “have,” and variations thereof such as “comprises” or “comprising,” will be understood to imply the inclusion of stated elements but not the exclusion of any other elements.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

The phrase “on a plane” or “in a plan view” means viewing the object portion from the top, and the phrase “on a cross-section” or “in a cross-sectional view” means viewing a cross-section of which the object portion is vertically cut from the side.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

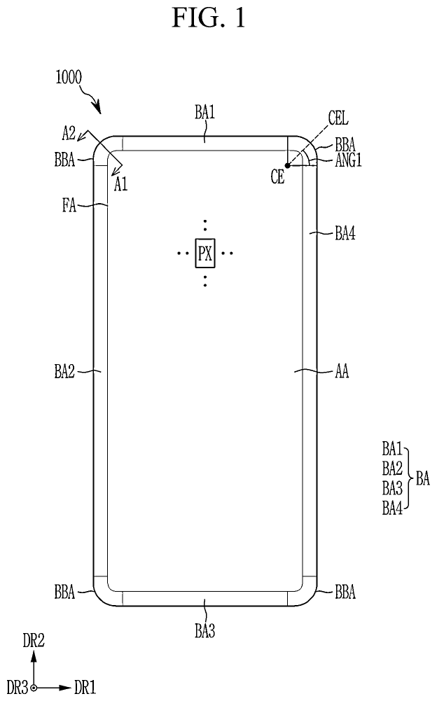

A display device according to an embodiment will now be described with reference to FIG. 1 to FIG. 6.

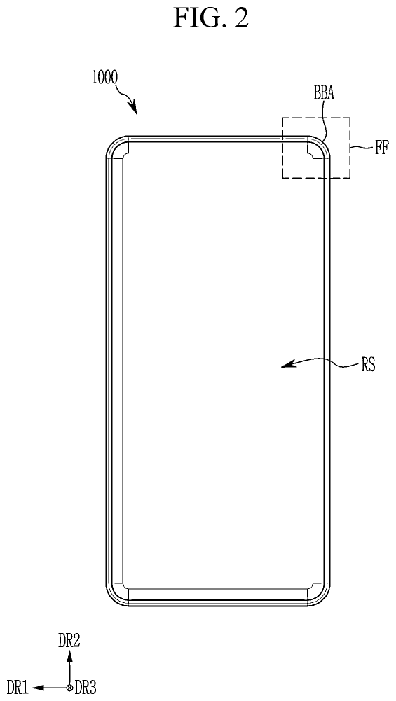

FIG. 1 shows a front top plan view of a display device according to an embodiment, and FIG. 2 shows a rear top plan view of a display device according to an embodiment.

Referring to FIG. 1, the display device 1000 may include a main display area AA for displaying an image in a front direction and an edge region PA disposed adjacent to or around the main display area AA. The main display area AA may form a flat area FA in a planar shape in parallel with a first direction DR1 and a second direction DR2, and without being limited thereto, and at least part thereof may not be flat.

The front direction may be a third direction DR3 that is perpendicular to the first direction DR1 and the second direction DR2. Hereinafter, on a plane or in a plan view may signify on a plane or in a plan view that is parallel to the first direction DR1 and the second direction DR2.

The main display area AA may include pixels PX for displaying images. The edge region PA may include pixels for displaying images, may include a display area, image, and/or may include a non-display area.

The edge region PA may include a lateral edge region BA for forming a lateral side in a plan view and a corner portion BBA disposed at corners.

Here, the display device is described to include the main display area AA, the edge region PA, the lateral edge region BA, and/or the corner portion BBA, and like. In the display panel 300 to be described, layers included by the display device also include the main display area AA, the edge region PA, the lateral edge region BA, and the corner portion BBA.

The lateral edge region BA may include at least one of first to fourth lateral edge regions BA1, BA2, BA3, and BA4 disposed in different directions. For example, the first lateral edge region BA1 may face the second direction DR2, that is, the upper side, the second lateral edge region BA2 may face the opposite direction to the first direction DR1, that is, the left, the third lateral edge region BA3 may face the opposite direction to the second direction DR2, that is, the lower side, and the fourth lateral edge region BA4 may face the first direction DR1, that is, the right. The first lateral edge region BA1 may face the third lateral edge region BA3, and the second lateral edge region BA2 may face the fourth lateral edge region BA4.

Two neighboring ones of the lateral edge regions BA1, BA2, BA3, and BA4 may meet a corner portion BBA. For example, the display device 1000 may include four corner portions BA facing different corner directions. However, the embodiments are not limited thereto, and the display device 1000 may include different number of corner portions BA.

The respective corner portions BA may have a round edge in a plan view. The round edge may substantially be circular or oval, but is not limited thereto. In case that the two lateral edge regions BA1, BA2, BA3, and BA4 contacting the respective corner portions BA contact two border lines contacting the corner portions BA and this contacting point is set to be a corner portion center CE, a line that passes through a center of the edge of the corner portion BBA from the corner portion center CE may be referred to as a corner portion center line CEL. An angle ANG1 formed between the corner portion center line CEL and the border line between the corner portion BBA and one of the lateral edge regions BA1, BA2, BA3, and BA4 contacting the corner portion BBA may be substantially about 45 degrees. In case that the border line between the corner portion BBA and the lateral edge regions BA1, BA2, BA3, and BA4 contacting the corner portion BBA is parallel to the first direction DR1 or the second direction DR2, the corner portion center line CEL may form substantially about 45 degrees with respect to the first direction DR1 or the second direction DR2.

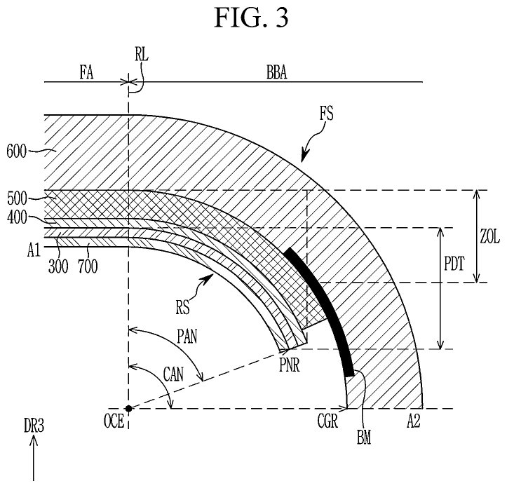

Referring to FIG. 2, the display device 1000 may not display images in the rear direction that is opposite to the front direction. In the disclosure, the rear direction is marked as the opposite direction to the third direction DR3, and the sides on which the respective layers included by the display device face the rear direction will be referred in common to as a rear side RS. In contrast, the sides on which they face the front direction will be referred in common to as a front side FS, as shown in FIG. 3. The structure on the rear side of the corner portion BBA of the display device 1000 will be described below.

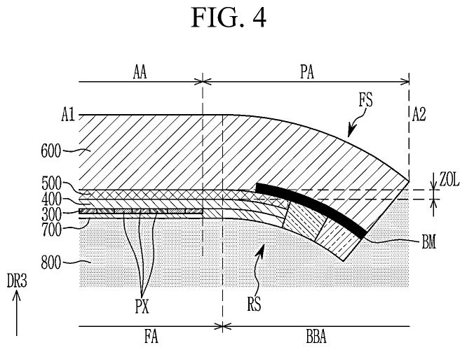

FIG. 3 shows a cross-sectional view of a display device with respect to a line A1-A2 of FIG. 1, and FIG. 4 shows another cross-sectional view of a display device with respect to a line A1-A2 of FIG. 1.

Referring to FIG. 3 together with FIG. 1 and FIG. 2, the display device may include a display panel 300. The display panel 300 may include the above-noted pixels PX. For example, the display panel 300 may include a substrate and transistors, capacitors, and light-emitting devices formed on the substrate and configuring a pixel circuit of the pixels PX. The display panel 300 may further include a driving circuit formed on the substrate and supplying driving signals for driving the pixel circuit of the pixels PX.

The display panel 300 may be flexible, bendable, and/or bent. The substrate included by the display panel 300 may be flexible, bendable, and/or bent. As shown in FIG. 3, the display panel 300 may be generally planar in the flat area FA, and the lateral edge region BA and the corner portion BBA, for example, the edge region PA may be bent with respect to respective curvature centers OCE.

Regarding the corner portion BBA shown in FIG. 3, a curvature radius PNR by which the rear side RS of the display panel 300 is bent with respect to the curvature center OCE may be constant over the entire corner portion BBA and may be variable depending on positions.

FIG. 3 shows the corner portion BBA, and the display panel 300 may bent with respect to the respective curvature centers OCE in the edge region PA excluding the corner portion BBA, for example, the first to fourth lateral edge regions BA1, BA2, BA3, and BA4 and may be bent in the same direction as on the corner portion BBA.

The curvature radius PNR of the display panel 300 in the at least two of the first to fourth lateral edge regions BA1, BA2, BA3, and BA4 may be different from at least one of the bent shapes, and differing from this, the curvature radius PNR of the display panel 300 in the first to fourth lateral edge regions BA1, BA2, BA3, and BA4 and the bent shape may be the same.

In case that the curvature radius PNR of the two neighboring ones of the lateral edge regions BA1, BA2, BA3, and BA4 contacting the corner portion BBA is different from the bent shape, the corresponding corner portion BBA may have at least two different curvature radii (PNR) and may be bent.

A polarization layer 400 overlapping the display panel 300 may be disposed on the display panel 300 in the front side FS direction.

The polarization layer 400 may reduce reflection of external light input from an upper portion of the front side FS of the display panel 300. In case that the external light passes through the polarization layer 400, is reflected on the display panel 300, and passes through the polarization layer 400 again, a phase of the external light may be changed. Therefore, the phase of the reflected light may be different from the phase of the external light input to the polarization layer 400 so destructive interference may be generated between the reflected light and the external light.

Although not shown in FIG. 3, an adhesive layer may be disposed between the polarization layer 400 and the display panel 300. A touch portion including a touch sensor for sensing touches may be disposed on the display panel 300 in the front side FS direction. The touch portion may be disposed between the display panel 300 and the polarization layer 400, but is not limited thereto. Insulating layers and touch electrode layers for configuring the touch portion may be formed on the display panel 300, or the touch portion formed on the substrate may be attached to the display panel 300.

A cover window 600 may be disposed on the polarization layer 400 in the front side FS direction. The cover window 600 may include at least one of glass and a polymer resin.

A light blocking layer BM may be disposed on a side (e.g., the rear side) of the cover window 400. The light blocking layer BM may be formed in the edge region PA including the corner portion BBA, and may be disposed on the edge of the edge region PA to block light.

An adhesive layer 500 may be disposed between the cover window 600 and the polarization layer 400.

At least one cover film may be disposed on the cover window 600 in the front side FS direction. In this case, an adhesive layer may be disposed between the cover window 600 and the cover film.

A protection film 700 for protecting the display panel 300 may be disposed below the display panel 300 in the rear side RS direction. The protection film 700 may support the display panel 300 and may protect the rear side RS of the display panel 300. The protection film 700 may include a plastic film such as a PET film, and is not limited thereto. An adhesive layer may be disposed between the display panel 300 and the protection film 700.

The edges of the protection film 700 may be arranged on the facing edges of the display panel 300 and may be equivalent to each other.

Many adhesive layers 500 disposed among the layers overlapping the display panel 300 may be optically clear, for example, they may include an optically clear adhesive (OCA), an optically clear resin (OCR), and a pressure sensitive adhesive (PSA), and may include a polymer resin.

The adhesive layers 500 overlapping the display panel 300, the polarization layer 400, the cover window 600, and the protection film 700 may be flat in parallel with the display panel 300 in the region that corresponds to the flat area FA of the display panel 300, and may be bent in parallel with the display panel 300 in the edge region PA of the display panel 300 including the corner portion BBA.

Referring to FIG. 3, the curvature radii of the respective layers with respect to the curvature center OCE may be different according to the positions of the layers. For example, referring to FIG. 3, the curvature radius CGR with respect to the curvature center OCE of the rear side RS of the cover window 600 disposed on the outermost part may be greater than the curvature radius PNR of the display panel 300.

An angle PAN to the edge of the display panel 300 with respect to an extension line of the border between the flat area FA and the edge region PA, for example, as shown in FIG. 3, the border between the flat area FA and the corner portion BBA as a reference line RL may be less than an angle CAN of the cover window 600 to the edge. Here, the curvature center OCE may be disposed on the reference line RL.

Referring to FIG. 3, a distance in the third direction DR3 between a point on which a virtual straight line extending in the third direction DR3 from the edge of the polarization layer 400 contacts the rear side RS of the cover window 600 and a point (i.e., the point on which the rear side RS of the cover window 600 is bent and starts) contacting the rear side RS of the cover window 600 contacting the reference line RL is referred to as a Z-overlap ZOL that is a measure for indicating a bending degree of the corner portion BBA. As the Z-overlap ZOL increases, the bending degree of the corner portion BBA may increase. The position for measuring the Z-overlap ZOL may correspond to the corner portion center line CEL described with reference to FIG. 1. For example, the Z-overlap ZOL may be measured on the cross-section of the display device along the corner portion center line CEL shown in FIG. 1.

As another example of the measure for indicating a bent depth degree of the edge region PA of the display device in addition to the corner portion BBA, as shown in FIG. 3, there may be a P-depth PDT for indicating a distance to the front side FS of the display panel 300 in the third direction DR3 contacting the reference line RL from the edge of the display panel 300. The P-depth PDT of the corner portion BBA may increase as the Z-overlap ZOL increases.

The cover window 600 may be rigid. In a process for manufacturing a display device, the display panel 300, the polarization layer 400, the adhesive layer 500, and the protection film 700 (which are referred to as a display panel module) that are flexible and are attached to each other may be provided to the rear side of the bent cover window 600, may be bent according to the shape of the cover window 600, and may be bonded to the cover window 600.

Additional characteristics of a cross-sectional structure of a display device according to an embodiment will now be described with reference to FIG. 4 together with FIG. 1 to FIG. 3.

Referring to FIG. 1 and FIG. 4, a main display area AA of the display device may be included in the flat area FA of the display panel 300. For example, the display panel 300 may be flat in some of or most of the main display area AA. However, without being limited thereto, the display panel 300 that is at least part of the main display area AA may be curved.

The display panel 300 of the edge region PA disposed outside the main display area AA may include the corner portion BBA and the lateral edge region BA. As shown in FIG. 4, the display panel 300 disposed near the main display area AA from among the edge region PA may be included in the flat area FA and the remaining region may belong to the corner portion BBA and the lateral edge region BA. However, without being limited thereto, the display panel 300 of the entire edge region PA may belong to the corner portion BBA and the lateral edge region BA.

The edge region PA in which the pixels PX are disposed may form a dead space. To reduce the area of the dead space and reduce the area of the edge region PA seen from the outside, it may be realized with a great curvature by increasing the Z-overlap ZOL of the corner portion BBA. To correspond to this, the bending degree that corresponds to the Z-overlap ZOL of the lateral edge region BA connected to the corner portion BBA needs to be increased. For example, the Z-overlap ZOL of the corner portion BBA may be substantially equal to or greater than 400 micrometers.

Referring to FIG. 4, regarding the display device, a support member 800 for supporting an external cover of the display device and the above-described many layers may be disposed below the protection film 700 in the rear side RS direction. The support member 800 may be made of (or may include) a rigid material including a metal, an alloy, and plastic, but is not limited thereto.

Various types of functional layers such as a cushion layer, a heat protecting sheet, a light blocking sheet, or a waterproof tape may be disposed between the protection film 700 and the support member 800.

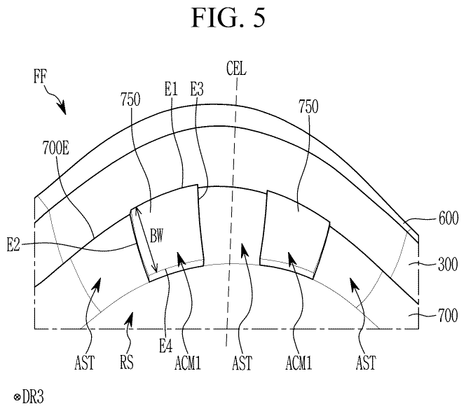

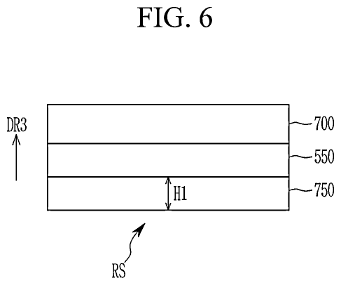

FIG. 5 shows a rear side view of a corner portion of a display device according to an embodiment, and FIG. 6 shows a schematic cross-sectional view of a corner portion of a display device according to an embodiment.

FIG. 5 shows an enlarged view of a region FF for indicating the corner portion BBA of the rear side RS of the display device 1000 in FIG. 2.

Referring to FIG. 5, the display device includes additional layers 750 disposed below the protection film 700 in the rear side RS direction. The additional layers 750 are disposed on the rear side RS of the protection film 700 that corresponds to the corner portion BBA. The respective additional layers 750 may not be continuously formed but may have an island shape on the corner portion BBA in a plan view of the rear side.

As the additional layers 750 have a thickness in the third direction DR3, the additional layer 750 may substantially have a column shape with a relatively low height.

The respective additional layers 750 may have various planar figure shapes in a plan view on the rear side RS. For example, the additional layers 750 may be polygons such as quadrangles or triangles, polygons with round edges, circles, or ovals. FIG. 5 shows quadrangular additional layers 750.

The respective additional layers 750 may include sides E1, E2, E3, and E4 extending in different directions. The sides E1, E2, E3, and E4 may include a first side E1 arranged on an outer edge 700E of the protection film 700 disposed on the corner portion BBA, and a second side E2 and third side E3 connected to respective ends of the first side E1.

As shown in FIG. 5, the first side E1 may correspond to the outer edge 700E of the protection film 700 so a gap between the first side E1 and the outer edge 700E of the protection film 700 may be substantially zero in a plan view. According to another embodiment, the first side E1 may have a gap of greater than zero from the outer edge 700E of the protection film 700. The first side E1 may be a curve or a line according to the shape of the outer edge 700E of the protection film 700.

The second side E2 may face the third side E3. The second side E2 and the third side E3 may be parallel to each other, or may be closer with each other when becoming distant from the first side E1 of the additional layer 750, depending on the shape of the additional layer 750.

The additional layer 750 may further include a fourth side E4 facing the first side E1. The fourth side E4 may be connected to the second side E2 and the third side E3. The fourth side E4 may extend in parallel with the first side E1. A length of the fourth side E4 may be substantially equal to or slightly less than a length of the first side E1.

The additional layers 750 disposed corresponding to one corner portion BBA may be spaced from each other. The two additional layers 750 provided near the corner portion center line CEL may be spaced from each other with the corner portion center line CEL therebetween. The two additional layers 750 may be spaced from the corner portion center line CEL.

FIG. 5 shows that two additional layers 750 are disposed corresponding to one corner portion BBA, and the number of the additional layers 750 is not limited thereto.

Referring to FIG. 6 together with FIG. 5, an adhesive layer 550 may be disposed between the protection film 700 and the additional layer 750. The adhesive layer 550 may include, e.g., an OCA, an OCR, and/or a PSA. In case that the adhesive layer 550 is included, the additional layer 750 may be attached to the rear side RS of the protection film 700 and may be fixed thereto with the adhesive layer 550 therebetween in the process for manufacturing a display device.

A thickness of the adhesive layer 550 in the third direction may be about 10 micrometers to 30 micrometers, and without being limited thereto, it is variable depending on conditions of the protection film 700 and the additional layer 750.

According to another embodiment, the adhesive layer 550 may be omitted unlike FIG. 6. The additional layer 750 may be disposed on the rear side RS of the protection film 700. In this case, in the process for manufacturing a display device, the additional layer 750 may be formed when applied to the rear side RS of the protection film 700 by various applying methods such as an inkjet, dispensing, or coating.

The additional layer 750 may include various types of resins or metals such as PET or PI. For example, in case that the additional layer 750 is attached to the rear side RS of the protection film 700 with the adhesive layer 550 therebetween, the additional layer 750 may include a metal plate and a resin film. For example, in case that the additional layer 750 is formed on the rear side RS of the protection film 700 without the adhesive layer 550 therebetween, the additional layer 750 may include a resin.

In case that the additional layer 750 is formed on the rear side RS of the protection film 700 without the adhesive layer 550 therebetween and the additional layer 750 and the protection film 700 include a same material, the protection film 700 and the additional layer 750 may be substantially integrally formed or integral with each other, and the portion on which the additional layer 750 is disposed in the corner portion BBA may be thicker than the remaining portion. For example, the additional layer 750 may protrude at the rear side RS of the protection film 700 in the rear direction.

A thickness H1 of the additional layer 750 in the third direction DR3 may be in a range of about 30 micrometers to about 150 micrometers, and without being limited thereto, it may be changeable depending on the condition such as rigidity of the additional layer 750 and the protection film 700.

The thickness H1 of the additional layers 750 disposed corresponding to one corner portion BBA may be constant, or the thickness H1 of the additional layers 750 on different positions may be different from each other. Further, the thickness H1 of one additional layer 750 may be constant, or the thickness H1 thereof may be variable depending on the portion.

According to the embodiment, the additional layers 750 may be disposed between the support member 800 and the protection film 700 shown in FIG. 4 on the corner portion BBA.

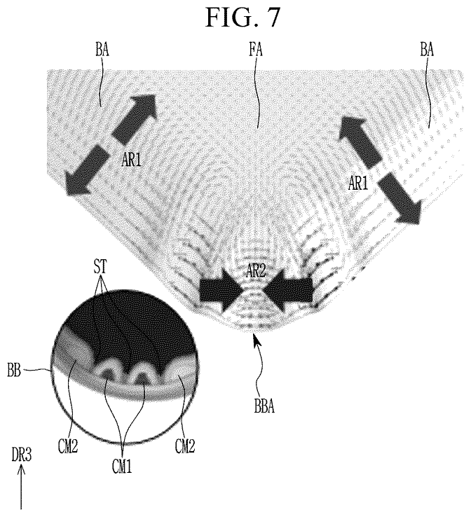

A display device according to a comparative example and a display device according to an embodiment will now be described with reference to FIG. 7 to FIG. 9 together with the display device according to an embodiment described with reference to FIG. 1 to FIG. 6.

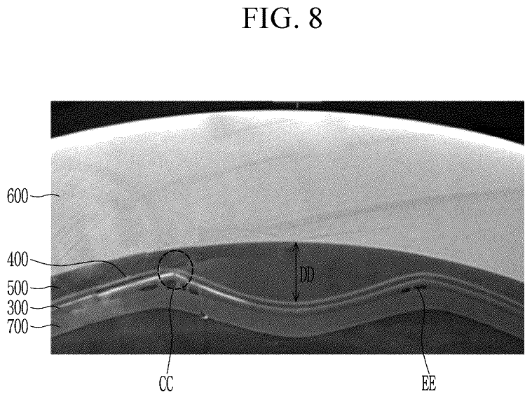

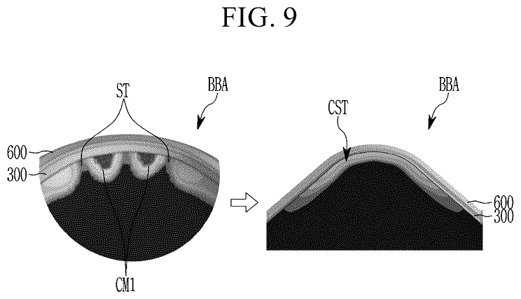

FIG. 7 shows a perspective view of a corner portion of a display panel included by a display device and compressing stresses applied to a corner portion according to a comparative example, FIG. 8 shows a cross-sectional view of a cross-sectional view of a corner portion of a display device according to a comparative example, and FIG. 9 shows compressing stresses applied to a corner portion of a display panel included by a display device according to a comparative example and compressing stresses applied to a corner portion of a display panel included by a display device according to an embodiment.

Referring to FIG. 7, in the case of the comparative example in which the display device includes no additional layer according to an embodiment, in case that the display panel 300, and the lateral edge regions BA and the corner portions BBA of various layers (i.e., display panel module) overlapping the display panel 300 are bent in the process for manufacturing a display device, a tensile stress and a compressing stress may be applied to the flexible display panel module including the display panel 300 and the layers (e.g., the polarization layer 400, the adhesive layer 500, the protection film 700, etc.) provided near the same.

In case that the lateral edge region BA of the display panel module is bent, as shown in FIG. 7, the tensile stress may be applied in an arrow AR1 direction, but the corner portion BBA may receive the compressing stress in an arrow AR2 direction of FIG. 7 because of an influence of the two adjacent lateral edge regions BA.

In detail, in case that the corner portion BBA of the display panel module is bent, compressed regions CM1 and CM2 to which the compressing stress is applied may be generated as marked in a region BB, and a tensile region ST to which the tensile stress is applied may be disposed between the adjacent compressed regions CM1 and CM2. For example, the compressing stress applied to the compressed region CM1 that corresponds to the center of the corner portion BBA may be the strongest.

As described above, in case that the Z-overlap ZOL of the corner portion BBA is increased to reduce an area of the edge region PA seen from the outside in the display device, for example, the area of the dead space, the compressing stress to the compressed regions CM1 and CM2 may be more increased to wrinkle the corner portion BBA of the display panel module, crack the same, or buckle the same as defects. The defects such as cracking or buckling may be shown as bending and cracking of the display panel 300, and the change of the thickness of the adhesive layer 500. The defects may be seen on the corner portion BBA of the edge region PA, may extend to the main display area AA to generate defects to the image, and may generate defects to an operation of the driving circuit disposed in the edge region PA.

For example, FIG. 8 shows an example of defects that may be generated on the corner portion of the display device according to a comparative example, showing the defects such as cracks in the display panel 300 as shown in a region CC, changes of the thickness of the polarization layer 400, changes of the thickness according to the position of the adhesive layer 500 as shown in a region DD, and generation of vapors on the adhesive layer between the display panel 300 and the protection film 700 as shown in a region EE.

Referring to FIG. 5 and FIG. 7, the additional layer 750 included by the display device according to the embodiment is disposed in compression corresponding regions ACM1 and ACM1 of the display panel module that corresponds to the compressed regions CM1 and CM2 having great compressing stresses in case that the display panel 300 and the corner portions BBA of the display panel module with various layers overlapping the display panel 300 are bent. FIG. 5 shows the additional layer 750 disposed in the compression corresponding region ACM1 that corresponds to the compressed region CM1. The display panel module among the compression corresponding regions ACM1 or of the region disposed near a lateral portion of the compression corresponding region ACM1 may include a tension corresponding region AST that corresponds to the tensile region ST.

In a like way that the compressed regions CM1 and CM2 and the tensile region ST are alternately disposed on the corner portion BBA as shown in FIG. 7, referring to FIG. 5, the compression corresponding region ACM1 of the protection film 700 and the tension corresponding region AST may be alternately disposed along the outer edge 700E of the protection film 700 on the corner portion BBA.

According to an embodiment, in case that the display panel 300 and the display panel module that represents layers provided near the same are bent, the additional layer 750 is partly formed in the compression corresponding region ACM1 that corresponds to the compressed region CM1 to which the compressing stress may be applied to relatively increase the thickness, thereby preventing generation of defects such as buckling or cracking that may be generated in the compression corresponding region ACM1 and its peripheral portions. For example, as the Z-overlap ZOL of the corner portion BBA increases, risks of defects such as buckling or cracking increase, but the risks may be reduced according to the embodiment. As the Z-overlap ZOL of the corner portion BBA deepens, the thickness H1 of the additional layer 750 and a width BW between the sides E1 and E4 of the additional layer 750 shown in FIG. 5 may be increased or rigidity of the additional layer 750 may be increased to reduce the generation of defects such as buckling or cracking.

In case that a minimum load for generating buckling to the display panel module is set to be a pressure critical load (PCR), the pressure critical load (PCR) of the compression corresponding region ACM1 in which the additional layer 750 is disposed is increased as an effect in case that the thickness is increased, and the risks of generation of buckling or cracking may be reduced by an amount of the increase.

Referring to FIG. 9, the left picture shows the compressed region CM1 caused by the compressing stress applied to the corner portion BBA of the display panel module and the tensile region ST receiving the tensile stress according to a comparative example of FIG. 7 and FIG. 8, and the right picture shows the compressed stress region CST applied to the corner portion BBA of the display panel module of the display device including the additional layer 750 according to an embodiment. Referring to the right picture of FIG. 9, the periodical strong compressing stress like the left picture is removed, and the compressed stress region CST that is continuously and weakly formed remains near the edge of the display panel module so it is found that the risks of generation of buckling or cracking at the corner portion BBA of the display panel module are substantially reduced.

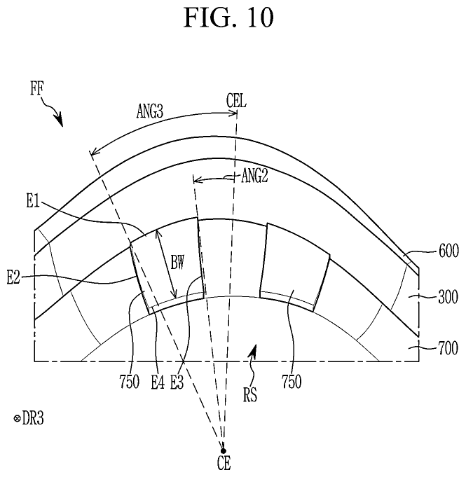

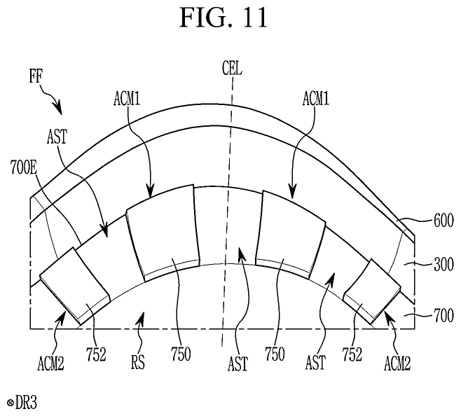

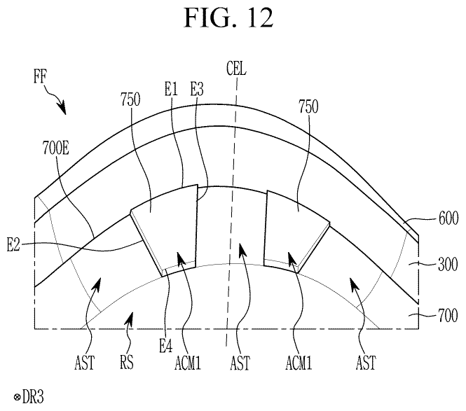

A display device and an additional layer 750 included by the display device according to an embodiment will now be described with reference to FIG. 10, FIG. 11, and FIG. 12 together with the above-noted drawings.

FIG. 10, FIG. 11, and FIG. 12 each show a rear side view of a corner portion of a display device according to an embodiment.

Referring to FIG. 10 together with FIG. 5, an angle ANG2 between a line generated by connecting the third side E3 of the additional layer 750 included by the display device and the corner portion center CE and the corner portion center line CEL may be greater than about 0 degrees and may be substantially about 3 degrees to about 7 degrees. An angle ANG3 between a line generated by connecting the second side E2 of the additional layer 750 and the corner portion center CE and the corner portion center line CEL is greater than the angle ANG2, and may be substantially about 15 degrees to about 20 degrees. However, without being limited thereto, the width between the sides E2 and E3, the width BW between the sides E1 and E4, and the angles ANG2 and ANG3 may be changeable according to the condition of the display panel module and a distribution of the compression corresponding region.

Referring to FIG. 11, the additional layers 750 included by the display device may further include additional layers 752 in addition to the additional layer 750 shown in FIG. 5.

The additional layers 752 may be disposed on the rear side RS of the protection film 700 that corresponds to the corner portion BBA, and the additional layers 752 may have island types that are not continuously formed on the corner portion BBA. The additional layers 752 may be disposed further inside the additional layer 750 with respect to the corner portion center line CEL. For example, the additional layer 750 may be disposed between the corner portion center line CEL and the additional layer 752. The respective additional layers 752 may be spaced from the neighboring additional layers 750, and the additional layers 752 may be spaced from each other with the corner portion center line CEL therebetween.

The additional layers 752 may have a similar shape to the additional layers 750. For example, the additional layer 752 may have a relatively low column shape, and may have various types of figure shapes such as polygons, polygons with round corners, circles, or ovals. FIG. 11 shows the additional layer 752 that is quadrangular in a plan view.

The additional layers 752 disposed near the respective additional layers 750 may be spaced from the additional layer 750.

Referring to FIG. 11 together with FIG. 7, the additional layer 752 may be disposed in the compression corresponding region ACM2 of the display panel module that corresponds to the compressed region CM2 neighboring the compressed region CM1 when the corner portion BBA of the display panel module is bent. The display panel module between the neighboring compression corresponding regions ACM1 and ACM2 may include the tension corresponding region AST that corresponds to the tensile region ST shown in FIG. 7. The additional layer may not be disposed in the tension corresponding region AST.

The areas of the respective additional layer 752 in a plan view may be different from the areas of the additional layers 750 in a plan view. In another embodiment, the areas of the respective additional layer 752 in a plan view may be substantially equal to the areas of the additional layers 750 in a plan view. FIG. 11 shows an example in which the areas of the respective additional layers 752 are different from the areas of the neighboring additional layers 750, and particularly shows the example in which the areas of the respective additional layers 752 are smaller than the areas of the additional layers 750, but is not limited thereto.

According to the embodiment, the additional layers 750 and 752 are partly formed in the compression corresponding regions ACM1 and ACM2 that correspond to the compressed regions CM1 and CM2 to which the compressing stresses may be applied in case that the display panel 300 and the display panel module representing the layers provided near the display panel 300 to thus relatively increase the thickness so the generation of defects such as buckling or cracking happening in the compression corresponding regions ACM1 and ACM2 and their peripheral regions may be efficiently prevented.

Referring to FIG. 12, the additional layer 750 included by the display device according to the embodiment is mostly equivalent to the additional layer 750, and the fourth side E4 may be shorter than the first side E1 compared to the additional layer 750 according to an embodiment shown in FIG. 5. For example, the additional layer 750 may substantially have a trapezoidal shape in a plan view. The respective additional layers 752 may have a similar shape to the additional layer 750 shown in FIG. 12 in case that the display device includes the additional layer 752 as shown in FIG. 11.

Depending on embodiments, the fourth side E4 of the additional layer 750 may be further shortened so that the respective additional layers 750 may have a triangular shape in a plan view.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display panel including:
a main display area that displays images and an edge region disposed adjacent to the main display area;
a protection film disposed below the display panel; and
at least one additional layer disposed below the protection film, wherein
the edge region includes a corner portion disposed on a corner, and
the at least one additional layer overlap the corner portion and are spaced from each other.

2. The display device of claim 1, wherein the at least one additional layer includes a resin.

3. The display device of claim 2, wherein the at least one additional layer contacts a rear side of the protection film.

4. The display device of claim 2, further comprising:
a first adhesive layer disposed between the at least one additional layer and the protection film.

5. The display device of claim 1, wherein the at least one additional layer includes a metal.

6. The display device of claim 5, further comprising:
a first adhesive layer disposed between the at least one additional layer and the protection film.

7. The display device of claim 1, wherein
the at least one additional layer includes a first additional layer and a second additional layer spaced from each other with a corner portion center line passing through a center of an edge of the corner portion.

8. The display device of claim 7, wherein
the at least one additional layer further includes a third additional layer spaced from the first additional layer and a fourth additional layer spaced from the second additional layer, and
the third additional layer and the fourth additional layer are spaced from each other with the corner portion center line between the third additional layer and the fourth additional layer.

9. The display device of claim 1, wherein the at least one additional layer includes:
a first side corresponding to a first edge of the protection film;
a second side connected to a first end of the first side; and
a third side connected to a second end of the first side and facing the second side.

10. The display device of claim 9, wherein
the at least one additional layer further includes a fourth side connected to the second side and the third side, and
the fourth side faces the first side.

11. The display device of claim 1, wherein the corner portion is bent with a curvature radius.

12. The display device of claim 11, wherein
the edge region further includes a first lateral edge region and a second lateral edge region connected to the corner portion,
the first lateral edge is bent with a first curvature radius, and
the second lateral edge is bent with a second curvature radius.

13. The display device of claim 12, wherein a curvature radius of the corner portion is changed according to positions.

14. The display device of claim 1, further comprising:
a polarization layer disposed on the display panel; and
a cover window disposed on the polarization layer,
wherein the cover window that corresponds to the edge region is bent.

15. The display device of claim 14, wherein in case that a distance in a front direction between a point on which a virtual straight line extending in the front direction from an edge of the polarization layer that corresponds to the corner portion contacts a rear side of the cover window and a point on which the cover window starts being bent is set to be a Z-overlap, the Z-overlap is substantially equal to or greater than about 400 micrometers.

16. A display device comprising:
a display panel including a main display area that displays images and an edge region disposed adjacent to the main display area;
a protection film disposed below the display panel;
a support member that is rigid and disposed below the protection film; and
at least one additional layer disposed between a rear side of the protection film and the support member, wherein
the edge region includes a corner portion disposed on a corner, and
the at least one additional layer contacts the corner portion.

17. The display device of claim 16, wherein
the at least one additional layer is spaced from each other, and
the at least one additional layer each has an island shape.

18. The display device of claim 17, wherein the at least one additional layer include a resin or a metal.

19. The display device of claim 17, wherein the corner portion and the protection film overlapping the corner portion are bent.

20. A display device comprising:
a display panel including a main display area that displays images and an edge region disposed adjacent to the main display area;
a protection film disposed below the display panel; and
a support member that is rigid and is disposed below the protection film, wherein
the edge region includes a corner portion disposed on a corner, and
thicknesses of the protection film overlapping the corner portion follows positions.
